(19) United States
(12) Patent Application Publication
(10) Pub. No.: US 2024/0130136 A1
(43) Pub. Date: Apr. 18, 2024

(54) SEMICONDUCTOR MEMORY DEVICE AND METHOD FOR FABRICATING THE SAME

(71) Applicant: IUCF-HYU (Industry-University Cooperation Foundation Hanyang University), Seoul (KR)

(72) Inventors: Yunheub SONG, Seoul (KR); Changhwan Choi, Seoul (KR); Bonchoel Ku, Seoil (KR)

(73) Assignee: IUCF-HYU (Industry-University Cooperation Foundation Hanyang Universityz0, seoul (KR)

(21) Appl. No.: 18/166,788

(22) Filed: Feb. 9, 2023

(30) Foreign Application Priority Data
Oct. 14, 2022 (KR) 10-2022-0132073

(51) Int. Cl. H10B 51/20; H10B 51/30

(52) U.S. Cl. CPC H10B 51/20; H10B 51/30

(57) ABSTRACT

Disclosed is a method for fabricating a semiconductor memory device which includes forming a channel hole inside a temporary stack structure including sacrificial layers and insulating layers alternately stacked on each other, forming a ferroelectric layer inside the channel hole, forming a stress control layer on an inner sidewall of the ferroelectric layer, performing a cooling process on an inner sidewall of the stress control layer, removing at least a portion of the stress control layer after the cooling process is performed, forming a vertical structure by sequentially forming a vertical channel layer and a vertical semiconductor layer on the ferroelectric layer, and removing the sacrificial layers from the temperature stack structure, and forming gate electrodes.

### CROSS-REFERENCE TO RELATED APPLICATIONS

This application claims priority under 35 U.S.C. § 119 to Korean Patent Application No. 10-2022-0132073 filed on Oct. 14, 2022, in the Korean Intellectual Property Office, the disclosures of which are incorporated by reference herein in their entireties.

### BACKGROUND

Embodiments of the present disclosure described herein relate to a semiconductor memory device, and more particularly, relate to a method for fabricating the same.

There has been required a semiconductor memory device capable of storing higher-capacity data in an electronic system necessary for data storage. Accordingly, studies and researches have been performed to increase a data storage capacity of the semiconductor memory device. For example, to increase the data storage capacity of the semiconductor memory device, there has been suggested a semiconductor memory device including memory cells arranged in a three dimension (3D), instead of memory cells arranged in a two dimension (2D).

### SUMMARY

Embodiments of the present disclosure provide a semiconductor memory device which consumes lower power and provides a higher data rate.

Embodiments of the present disclosure provide a method for fabricating a semiconductor memory device which consumes lower power and provides a higher operating rate.

According to an embodiment, a method for fabricating a semiconductor memory device, includes forming a channel hole inside a temporary stack structure including sacrificial layers and insulating layers alternately stacked on each other, forming a ferroelectric layer inside the channel hole, forming a stress control layer on an inner sidewall of the ferroelectric layer, performing a cooling process on an inner sidewall of the stress control layer, removing at least a portion of the stress control layer after the cooling process is performed, forming a vertical structure by sequentially forming a vertical channel layer and a vertical semiconductor layer on the ferroelectric layer, and removing the sacrificial layers from the temperature stack structure and forming gate electrodes.

According to an embodiment, a semiconductor memory device includes a stack structure including gate electrodes and insulating layers alternately stacked on a substrate, and a vertical structure provided inside the stack structure. The vertical structure includes a vertical semiconductor layer having a pillar shape, a ferroelectric layer provided between the gate electrodes and the vertical semiconductor layer, a vertical channel layer interposed between the ferroelectric layer and the vertical semiconductor layer, and a stress control layer interposed between the ferroelectric layer and the vertical channel layer. The stress control layer is directly connected to the ferroelectric layer.

### BRIEF DESCRIPTION OF THE FIGURES

The above and other objects and features of the present disclosure will become apparent by describing in detail embodiments thereof with reference to the accompanying drawings.

FIG. 1 is a circuit diagram illustrating a cell array of a semiconductor memory device according to embodiments of the present disclosure.

FIG. 2 is a circuit diagram illustrating a unit memory cell according to an embodiment of the present disclosure.

FIG. 3 is a plan view illustrating a cell array of a semiconductor memory device according to embodiments of the present invention, and FIG. 4 is a cross-sectional view taken along line I-I′ of FIG. 3.

FIG. 5 is a schematic perspective view illustrating a cell string of a semiconductor memory device according to embodiments of the present disclosure.

FIGS. 6, 7, 8, and 9 are enlarged views of part P of FIG. 4.

FIG. 10 is a cross-sectional view taken along line I-I′ of FIG. 3.

FIG. 11 is a flowchart illustrating a method for fabricating a semiconductor memory device according to the present disclosure.

FIGS. 12 to 24 are views to describe the fabricating method of FIG. 11 step by step.

### DETAILED DESCRIPTION

Hereinafter, embodiments of the present disclosure may be described in detail and clearly to such an extent that an ordinary one in the art easily implements the invention.

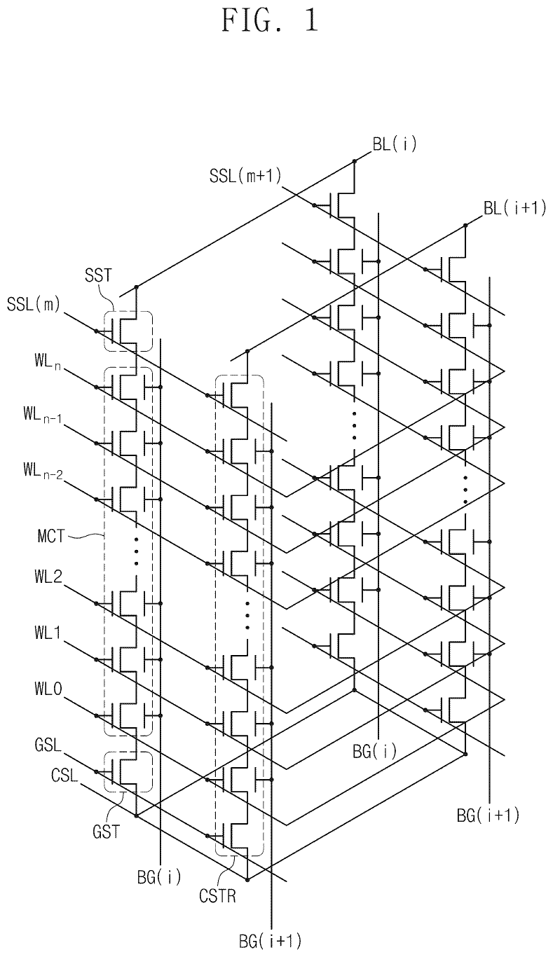

FIG. 1 is a circuit diagram illustrating a cell array of a semiconductor memory device according to embodiments of the present disclosure.

Referring to FIG. 1, a cell array of a semiconductor memory device according to embodiments of the present disclosure may include bit lines BL(i) and BL(i+1), a common source line CSL, word lines WL0, WL1 . . . , and WLn, string selection lines SSL(m) (or upper selection lines), ground selection lines GSL(1) (or lower selection lines), and cell strings CSTR between the bit lines BL(i) and BL(i+1), and the common source line CSL.

The bit lines BL(i) and BL(i+1) may be arranged in a 2D, and a plurality of cell strings CSTR may be connected in parallel to each of the bit lines BL(i) and BL(i+1). The plurality of cell strings CSTR may be commonly connected to a common source line CSL. In other words, the plurality of cell strings CSTR may be interposed between the plurality of bit lines BL(i) and BL(i+1) and one common source line CSL. According to an embodiment, each of the cell strings CSTR may include a ground selection transistor GST connected to the common source line CSL, string selection transistors SST connected to the bit line BL(i) and the bit line BL(i+1), and a plurality of memory cells MCTs interposed between the ground selection transistor GST and the string selection transistor SST. The ground selection transistor GST, the string selection transistor SST, and the memory cells MCT may be connected to each other in series. According to embodiments, each of the cell strings CSTR may include one or a plurality of string selection transistors SST and one or a plurality of ground selection transistors GST.

The ground selection line GSL, the plurality of word lines WL, and the string selection lines SSL may be used for gate electrodes of the ground selection transistor GST, the memory cells WL, and the string selection transistor SST, respectively.

The string selection lines SSL may control the electrical connection between the bit lines BL(i) and BL(i+1) and the cell strings CSTR, and the ground selection line GSL may control the electrical connection between the cell strings CSTR and the common source line CSL. In addition, the plurality of word lines WL may be to control the memory cells MCT. The memory cells MCT positioned at the same level on the cell strings CSTR may be connected to the same word line WL.

One of the cell strings CSTR may be selected by one selected from the bit lines BL(i) and BL(i+1) and one selected from the string selection line SSL(m) and SSL(m+1). Furthermore, in one selected cell string CSTR, one of the memory cells MCT may be selected by one selected from the word lines WL0, . . . , and WLn.

According to embodiments, each of the memory cells MCT may include an information storage element having a ferroelectric material. Data may be recorded or erased in each memory cell MCT by using the polarization change of a dipole in the information storage element by a voltage input to the word lines WL0, . . . , and WLn. The semiconductor memory device may operate with lower power consumption by using the information storage element having the ferroelectric material, and a more rapid operating speed may be implemented.

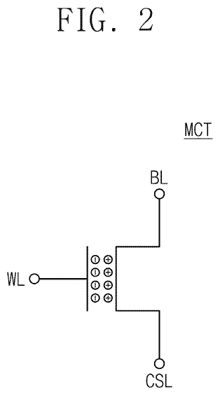

FIG. 2 is a circuit diagram illustrating a unit memory cell according to an embodiment of the present disclosure.

Referring to FIG. 2, each memory cell MCT may be controlled by a word line WL. Each memory cell MCT may include a gate electrode, a source electrode, a drain electrode, and a channel between the source electrode and the drain electrode. The gate electrode of each memory cell MCT may be connected to the word line WL, and the common source line CSL may be connected to the source electrode. Each memory cell MCT may include a ferroelectric layer FEL, which serves as a memory layer (or a data storage layer), between the channel region and the gate electrode.

The ferroelectric layer FEL may be formed of a ferroelectric material to represent a data value based on a polarization state of charges. The ferroelectric layer FEL may represent a binary data value or a multi-level data value, based on the polarization state of charges. Hereinafter, the ferroelectric material may include at least one of HfOx, PZT(Pb(Zr, Ti)O3), PTO(PbTiO₃), SBT(SrBi₂Ti₂O₃), BLT(Bi(La, Ti)O₃), PLZT(Pb(La, Zr)TiO₃), BST(Bi(Sr), Ti)O₃), barium titanate (BaTiO₃), P(VDF-TrFE), PVDF, AlOx, ZnOx, TiOx, TaOx, or InOx which is doped with at least one of HfOx, Al, Zr or Si having an orthorhombic crystal structure.

The ferroelectric layer FEL may have a spontaneous dipole (electric dipole), that is, spontaneous polarization, due to the non-centrosymmetric distribution of charges in each memory cell MCT. The ferroelectric layer FEL has remnant polarization by a dipole even in the absence of an external electric field. In addition, the direction of polarization may be switched by an external electric field.

In other words, the ferroelectric layer FEL may have a positive or negative polarization state, and the polarization state may be varied by an electric field applied to the ferroelectric layer FEL during a program operation. Since the polarization state of the ferroelectric layer FEL may be maintained even if power is cut off, the semiconductor memory device may operate as a nonvolatile memory device. According to embodiments, the polarization state of the ferroelectric layer FEL may be determined by a voltage difference between the channel region and the gate electrode.

For example, during program operation, the channel region in the memory cell MCT may be depleted by a first program voltage applied to the gate electrode, and the polarity of the ferroelectric layer FEL may be changed by the voltage difference between a second program voltage applied to the gate electrode and the channel region. The voltage difference between the second program voltage and the channel region may be greater than or equal to the minimum voltage required to change the polarization of the ferroelectric layer FEL.

Data stored in the memory cell MCT may be read by measuring a current flowing through a channel region of the selected memory cell MCT, during an operation of reading data out of the memory cell MCT. In addition, a plurality of memory cells may be erased at the same time by applying an erase voltage to the gate electrode.

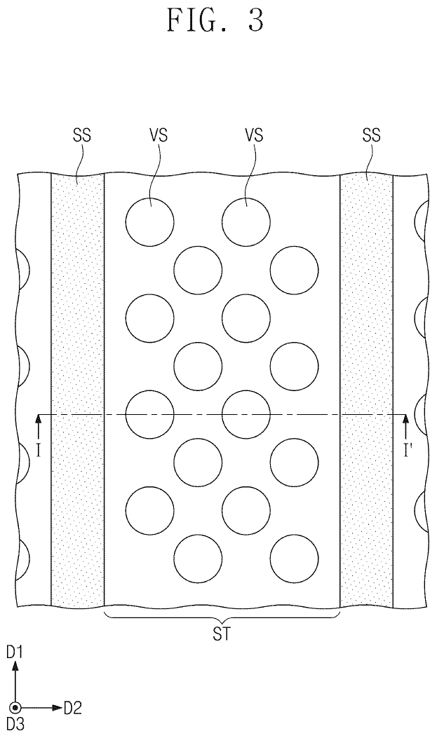

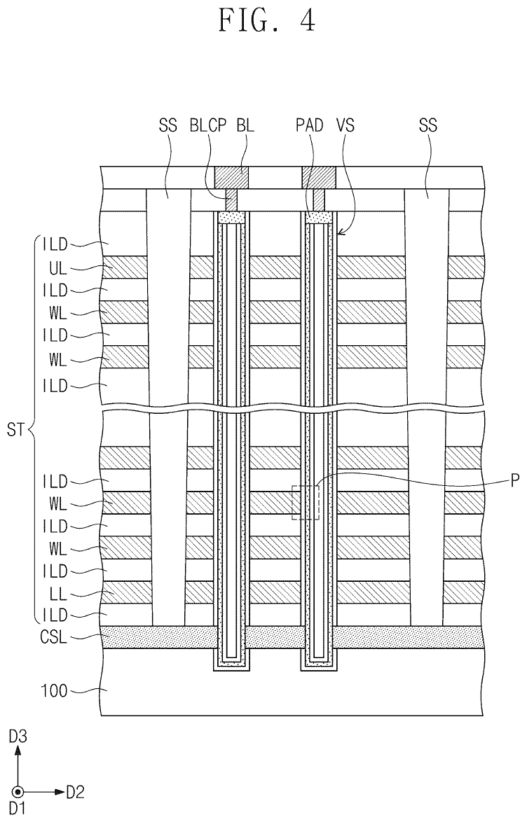

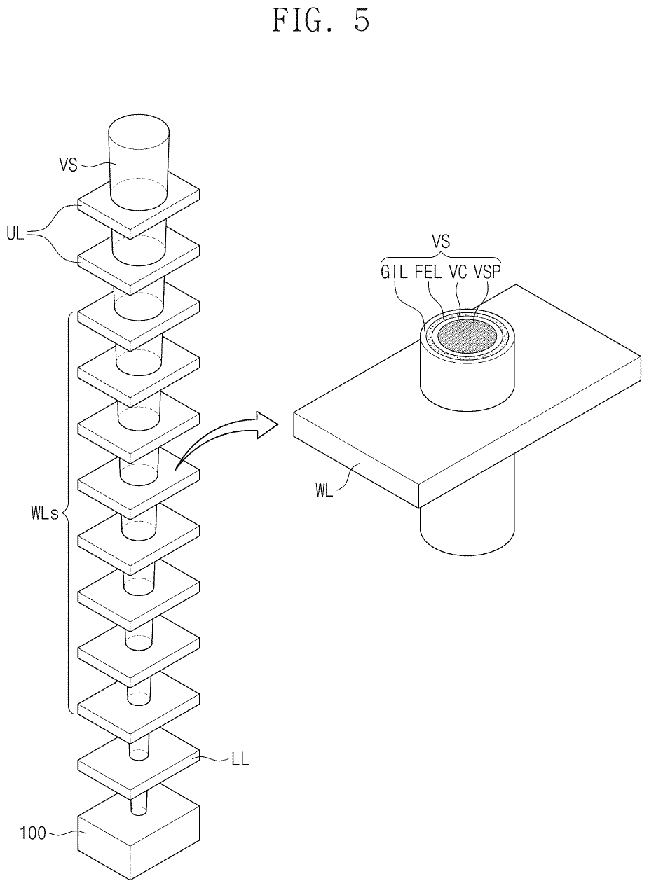

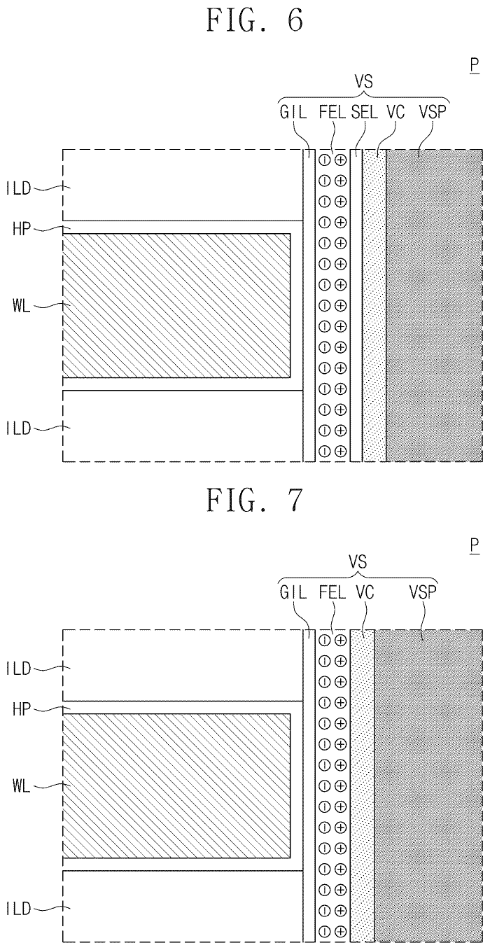

FIG. 3 is a plan view illustrating a cell array of a semiconductor memory device according to embodiments of the present invention, and FIG. 4 is a cross-sectional view taken along line I-I′ of FIG. 3. FIG. 5 is a schematic perspective view illustrating a cell string of a semiconductor memory device according to embodiments of the present disclosure. FIGS. 6, 7, 8, and 9 are enlarged views of part P of FIG. 4.

Referring to FIGS. 3 and 4, a semiconductor memory device according to embodiments may include a stack structure ST, vertical structures VS, and bit lines BL on a substrate 100. According to embodiments, cell strings (CSTR in FIG. 1) illustrated in FIG. 1 may be integrated on the substrate 100, and the stack structure ST and the first vertical structures VS1 may constitute cell strings (see CSTR in FIG. 1).

The substrate 100 may include a semiconductor material, an insulating material, or a conductive material. The substrate 100 may include a semiconductor doped with dopants having a first conductive type (e.g., N-type) and/or an intrinsic semiconductor in a state in which impurities are not doped. The substrate 100 may have a crystal structure including at least any one selected from among a single crystal, amorphous, and polycrystalline.

The stack structure ST may be disposed on the substrate 100 and may extend in the first direction D1. The stack structure ST may include gate electrodes UL, WL, LL, and insulating layers ILD alternately stacked in a third direction D3 perpendicular to the first and second directions D1, D2 crossing each other.

The gate electrodes UL, WL, and GL may include, for example, at least one selected from a doped semiconductor (e.g., doped silicon), metal (e.g., tungsten, copper, aluminum), a conductive metal nitride (e.g., a titanium nitride or tantalum nitride), or a transition metal (e.g., titanium, or tantalum). The insulating layers ILD may include a silicon oxide layer and/or a low dielectric layer. According to embodiments, the semiconductor memory device may be a vertical NAND flash memory device. In this case, the electrodes SSL, WL, and GSL of the stack structure ST may be used as string selection lines SSL, word lines WL, and ground selection lines GSL described with reference to FIG. 1.

The common source line CSL may be interposed between the substrate 100 and the stack structure ST. The common source line CSL may extend in the first direction D1 in parallel with the stack structure ST. The common source line may include a semiconductor material and a conductive material.

A plurality of vertical structures VS may pass through the stack structure ST. Referring to FIG. 5, the plurality of vertical structure VS may extend in a third direction perpendicular to a top surface of the substrate 100. The vertical structure VS may pass through conductive materials forming the ground selection lines GSL, word lines WLs, and the string selection lines SSL. In other words, the ground selection lines GSL, the word lines WLs, and the string selection lines SSL may surround the vertical structure VS. The word lines WLs may include dummy word lines that are not used for data storage. The dummy word line may be used for various purposes. Memory cells according to embodiments may be provided between the vertical structures VS and the gate electrodes, respectively.

The vertical structure VS may be arranged in one direction or in a zigzag form, when viewed in a plan view. The width or diameter of the vertical structure VS may be increased, as the distance from the substrate 100 is increased. In other words, the vertical structure VS may have a sidewall inclined with respect to a top surface of the substrate 100.

In more detail, referring to FIGS. 5 and 6, each of the vertical structures VS may include a vertical semiconductor layer VSP, a vertical channel layer VC between the gate electrodes WL and the vertical semiconductor layer VSP, and a ferroelectric layer FEL between the vertical channel layer VC and the gate electrodes WL. In the vertical structure VS, the ferroelectric layer FEL, the stress control layer SEL, the vertical channel layer VC, and the vertical semiconductor layer VSP may be sequentially provided inwardly.

The vertical semiconductor layer VSP may have the form of a pillar extending in the third direction D3. Alternatively, the vertical semiconductor layer VSP may have a U-shaped cross-section and may have an inner part filled with an insulating material. The vertical semiconductor layer VSP may be spaced apart from the substrate 100, and a portion of the ferroelectric layer FEL may be positioned between the vertical semiconductor layer VSP and the substrate 100.

The vertical semiconductor layer VSP may be formed of a material that helps to diffuse charges or holes in the vertical channel pattern VCP. In more detail, the vertical semiconductor layer VSP may be formed of a material having excellent charge and hole mobility. For example, the vertical semiconductor layer VSP may be formed of a semiconductor material doped with impurities, an intrinsic semiconductor material which is not doped with the impurities, or a polycrystalline semiconductor material. In more detail, the vertical semiconductor layer VSP may be formed of polysilicon doped with the same first conductivity type impurities (e.g., P-type impurities) as the substrate (SUB). In other words, the vertical semiconductor layer VSP may improve the electrical characteristics of the 3D flash memory to improve the speed of the memory operation.

Referring to FIG. 6 together, the vertical channel layer VC may surround a sidewall of the vertical semiconductor layer VSP and may extend in the third direction D3. The vertical channel layer VC may have a uniform thickness, on a sidewall of the vertical semiconductor layer VSP.

The vertical channel layer VC may include a semiconductor material, such as silicon (Si), germanium (Ge), or a mixture thereof. The vertical channel layer VC including the semiconductor material may be used as channels of the string selection transistor SST, the ground selection transistor GST, and channels of the memory cells MCT described with reference to FIG. 1. The vertical channel layer VC may have the form of a pipe or a macaroni form having the closed lower end. The vertical channel layer VC may have a U-shaped form. For example, a portion of the sidewall of the vertical channel layer VC may make contact with the common source line CSL.

A conductive pad PAD may be provided on a top surface of the vertical channel layer VC and a top surface of the vertical semiconductor layer VSP. The conductive pad PAD may be connected to an upper portion of the vertical channel layer VC and an upper portion of the vertical semiconductor layer VSP. A sidewall of the conductive pad PAD may be surrounded by the ferroelectric layer FEL. The top surface of the conductive pad PAD may be substantially coplanar with the top surface of each of the stack structures ST (the top surface of the uppermost part of interlayer insulating layers (ILD)).

The conductive pad PAD may be formed of an impurity-doped semiconductor or a conductive material. For example, the conductive pad PAD may be formed of a semiconductor material doped with impurities different from the impurities of the vertical semiconductor film VSP (more exactly, the impurities in the second conductive type (e.g., N-type) different from the first conductive type (e.g., P-type)).

The conductive pad PAD may reduce contact resistance between the bit line BL to be described later and the vertical channel layer VC (or the vertical semiconductor layer VSP).

Although the vertical channel structures VS have a structure including the conductive pad PAD, the present disclosure is not limited thereto. For example, the vertical channel structures VS may have a structure without the conductive pad PAD. In this case, as the conductive pad PAD is omitted from the vertical channel structures VS, the vertical channel pattern VCP and the vertical semiconductor layer VSP may extend in three directions such that the top surfaces of the vertical channel pattern VCP and the vertical semiconductor layer VSP are substantially coplanar with the top surfaces (i.e., the top surfaces of the uppermost parts of the interlayer insulating layers ILD) of the stacked structures ST. In addition, in this case, the bit line contact plug (BLCP), which will be described later, may be electrically connected to the vertical channel layer VC while directly making contact with the vertical channel layer VC, instead of being indirectly electrically connected to the vertical channel layer VC through the conductive pad PAD.

The stress control layer SEL may surround a sidewall of the vertical channel layer VC and may extend in the third direction D3. The stress control layer SEL may have a substantially uniform thickness on the sidewall of the vertical channel layer VC. The thickness of the stress control layer SEL may be less than the thickness of the ferroelectric layer and may be less than the thickness of the vertical channel layer VC. For example, the thickness of the stress control layer SEL may be 5 to 50 nanometers.

As described later, since the stress control layer SEL is formed to make contact with the inner wall of the ferroelectric layer FEL, stress with the ferroelectric layer FEL is caused during a cooling process, thereby improving orthorhombic characteristics of the ferroelectric layer FEL. The stress control layer SEL may include a material to cause stress with the ferroelectric-based ferroelectric layer FEL during a cooling process.

The stress control layer SEL may have a pipe form or a macaroni form having the closed lower end. The vertical channel layer VC may have a U-shaped form.

The ferroelectric layer FEL may surround the outer wall of the stress control layer SEL and may extend in the third direction D3. The ferroelectric layer FEL may have a substantially uniform thickness on the sidewall of the stress control layer SEL.

The vertical channel layer VC may have the form of a pipe or a macaroni form having the closed lower end. The vertical channel layer VC may have a U-shaped form. Although the ferroelectric layer (FEL) is illustrated as a single layer in the drawings, as another example, the ferroelectric layer (FEL) may include a plurality of ferroelectric layers.

According to embodiments, the ferroelectric film FEL may include a ferroelectric material having polarization characteristics by an electric field applied thereto. The ferroelectric material may be made of a dielectric material including hafnium. For example, the ferroelectric film FEL may include HfO2, HfSiO2 (Si-doped HfO₂), HfAlO₂ (Al-doped HfO2), HfSiON, HfZnO, HfZrO₂, ZrSiO₂, ZrSiO2, ZrSiO₂, LaAlfO₂, or HfScO₂.

A gate insulating layer GIL may surround a sidewall of the ferroelectric layer FEL and may extend in the third direction D3. The gate insulating layer GIL may have a uniform thickness on the ferroelectric layer FEL. The gate insulating layer GIL may insulate an insulating material different from that of the ferroelectric layer FEL or a non-ferroelectric material. For example, the gate insulating layer GIL may surround a sidewall of the ferroelectric layer FEL, on a top surface of the common source line CSL.

The gate insulating layers GIL may include, for example, a single layer selected from a high dielectric layer, a silicon oxide layer, a silicon nitride layer, and a silicon oxynitride layer, or a combination thereof. For example, the high dielectric film may include at least one of a hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate. The horizontal insulating pattern HP may conformally cover one side walls of the gate electrodes SSL, WL, and GSL adjacent to the vertical structures VS, and top and bottom surfaces of the electrodes SSL, WL, and GSL. The horizontal insulating pattern HP may include a high dielectric layer such as an aluminum oxide layer and a hafnium oxide layer.

According to an embodiment, referring to FIG. 7, the stress control layer SEL may be omitted from the vertical structure VS, and the ferroelectric layer FEL may be directly connected to the vertical channel layer VC.

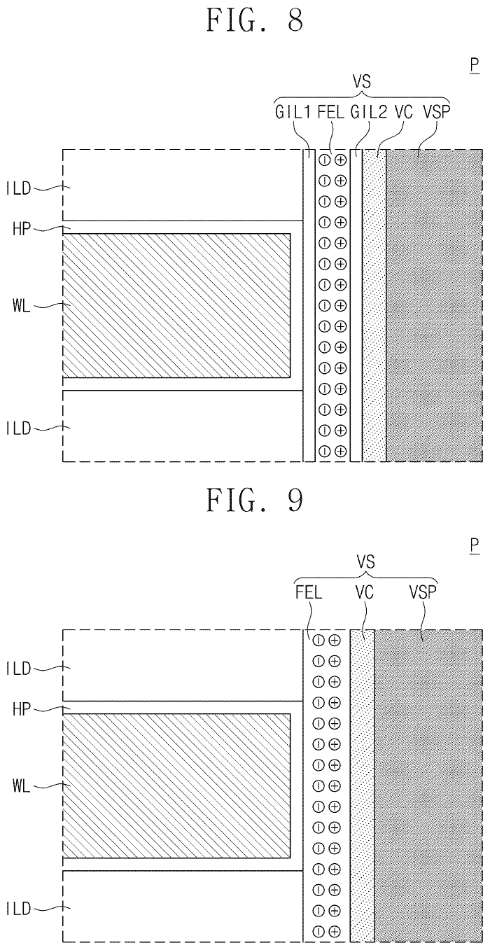

According to an embodiment, referring to FIG. 8, the vertical structure VS may include a first gate insulating layer GIL1 between the ferroelectric layer FEL and the gate electrode WL, and a second gate insulating layer GIL2 between the vertical channel layer VC and the ferroelectric layer FEL. The first gate insulating layer GIL1 and the second gate insulating layer GIL2 may insulate an insulating material different from that of the ferroelectric layer FEL or may include a non-ferroelectric material.

According to an embodiment, referring to FIG. 9, the gate insulating layer GIL may not be provided in the vertical structure VS.

Referring back to FIGS. 3 and 4, a separation structures SS may pass through the stack structure ST on the substrate 100. Each of the separation structures SS may include an insulating layer covering a sidewall of the stack structure ST. Each of the separation structures SS may have a single-layer structure or a multi-layer structure.

The separation structures SS may extend in the first direction D1 in parallel to the stack structure ST and may be spaced apart from each other in the second direction D2 crossing the first direction D1. The stack structure ST may be interposed between the separation structures SS adjacent to each other. The separation structures SS may be disposed on the substrate 100 or the common source line CSL. The top surfaces of the separation structures SS may be positioned at substantially the same level, and may be positioned at a higher level than the top surfaces of the vertical structures VS.

Although bit lines BL are omitted when viewed in a plan view, the bit lines BL may extend in the second direction D2 across the stack structure ST.

The bit lines BL may be connected to the conductive pad PAD of each vertical structure VS through the bit line contact plugs BLPG to be connected to the vertical channel layer VC.

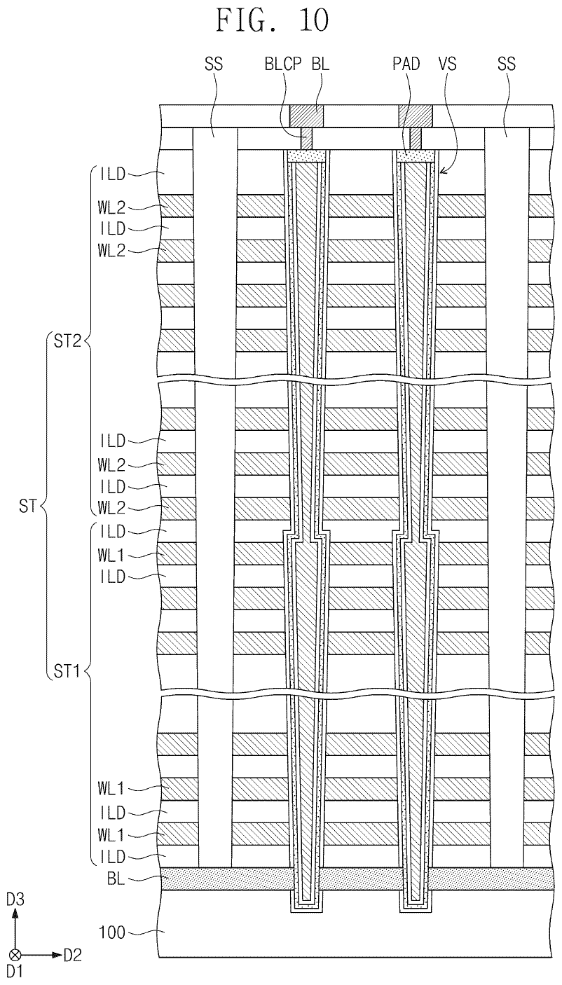

FIG. 10 is a cross-sectional view taken along line I-I′ of FIG. 3. According to the present embodiment, the details of the technical features the same as those described with reference to FIGS. 3 to 9 are omitted, and the difference in technical feature will be described below.

Referring to FIGS. 3 and 10, the stack structure ST on the substrate 100 may include a first stack structure ST1 and a second stack structure ST2 on the first stack structure ST1. The first stack structure ST1 may include first gate electrodes WL1 stacked in a direction perpendicular to the substrate 100 (that is, in the third direction D3). The first stack structure ST1 may further include first insulating layers ILD for separating the stacked first gate electrodes WL1 from each other. The first insulating layers ILD1 and the first gate electrodes WL1 of the first stack structure ST1 may be alternately stacked in the third direction D3. A second insulating layer ILD may be provided on the uppermost part of the first stack structure ST1.

The second stack structure ST2 may include second gate electrodes WL2 stacked on the first stack structure ST1 in the third direction D3. The second stack structure ST2 may further include second insulating layers ILD2 to separate the stacked first gate electrodes WL2 from each other. The second insulating layers ILD2 and the second gate electrodes WL2 of the second stack structure ST2 may be alternately stacked in the third direction D3.

Each of the first vertical structures VS1 may include a first vertical extension part formed through the first stack structure ST1, a second vertical extension part formed through the second stack structure ST2, and an extension part between the first vertical extension part and the second vertical extension part. The extension part may be provided in the uppermost interlayer insulating layer ILD of the first stack structure ST1. The diameter of the vertical structure VS may increase rapidly in the extension part. Furthermore, according to the above-described embodiment, the vertical structure VS may have the substantially same shape as that of the first vertical structure VS1 provided in the connection area.

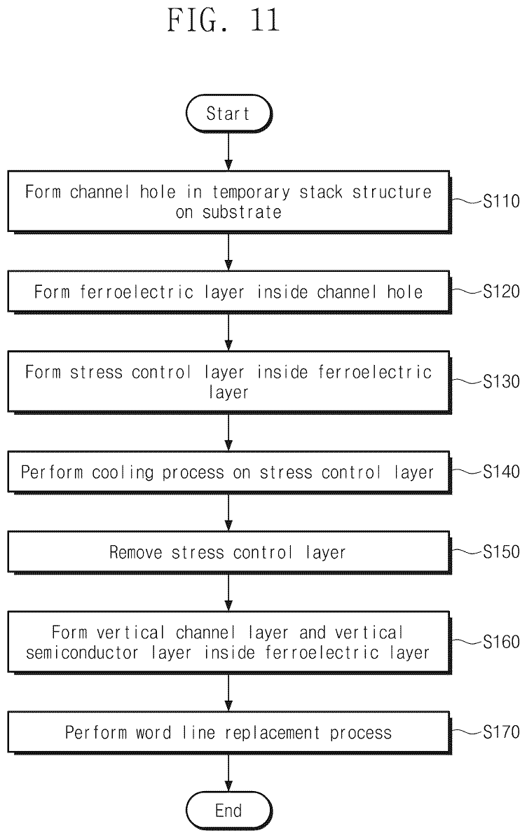

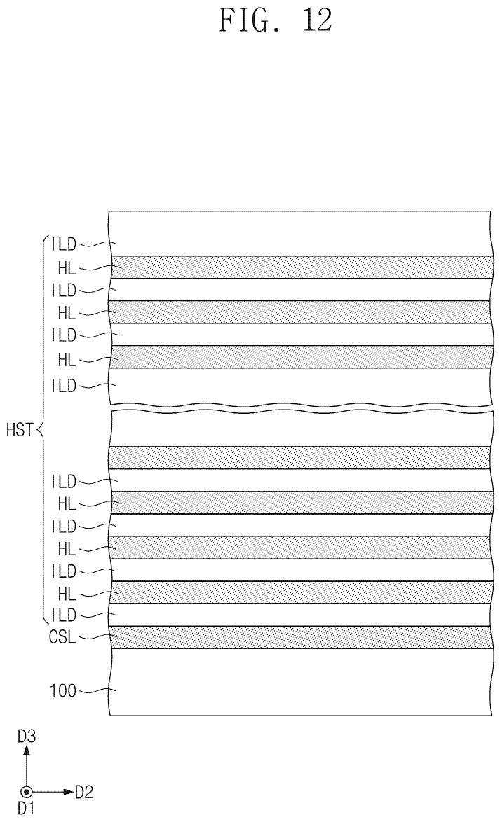

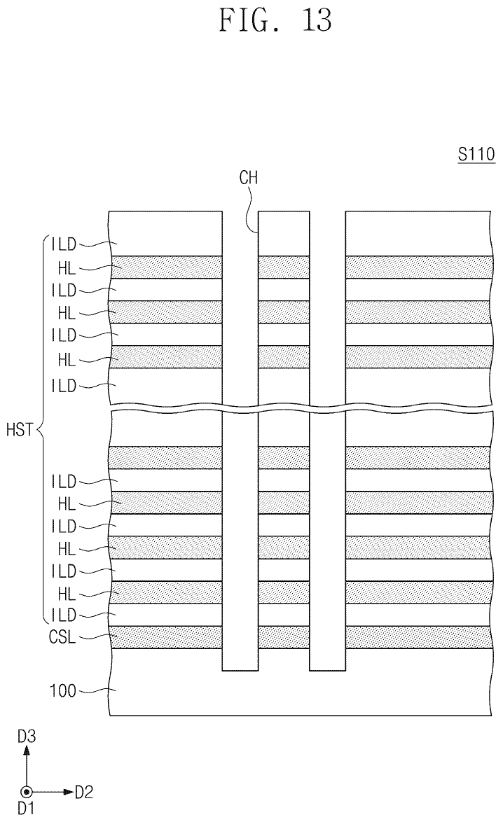

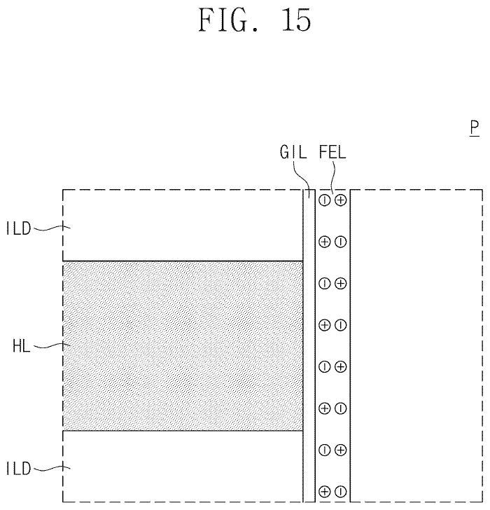

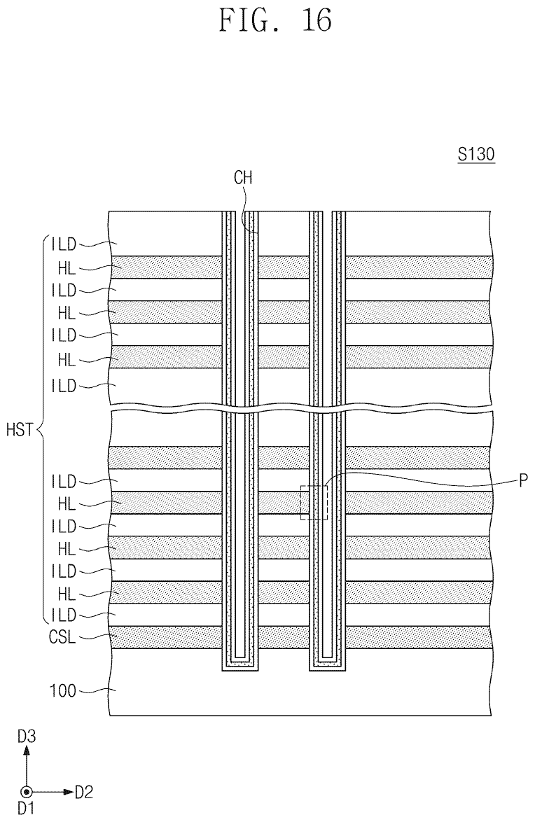

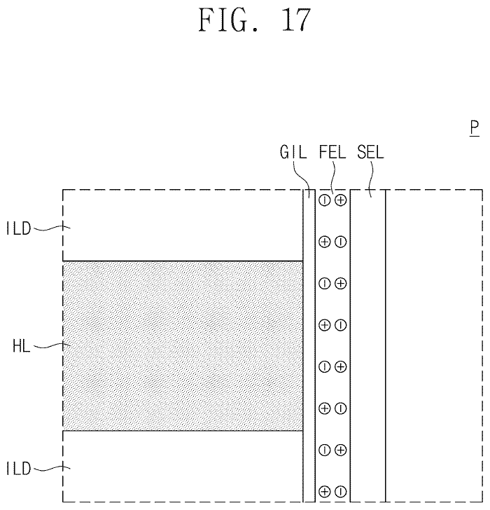

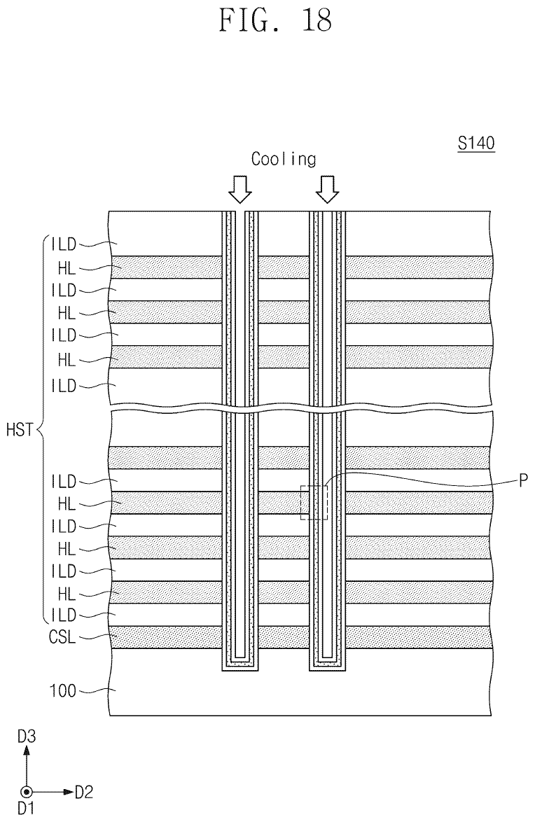

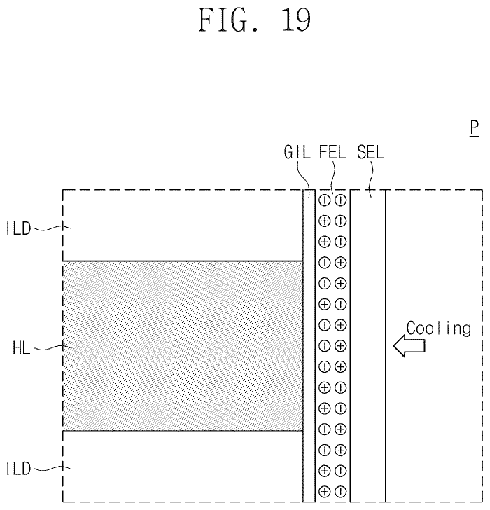

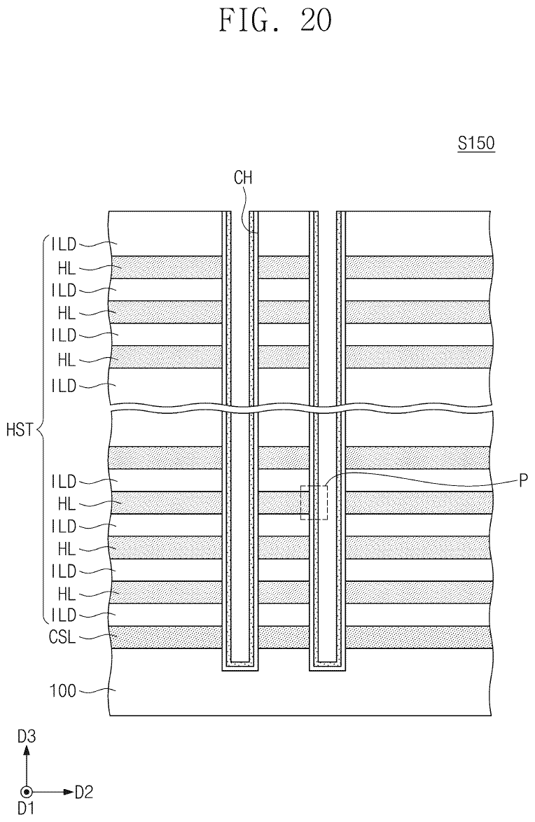

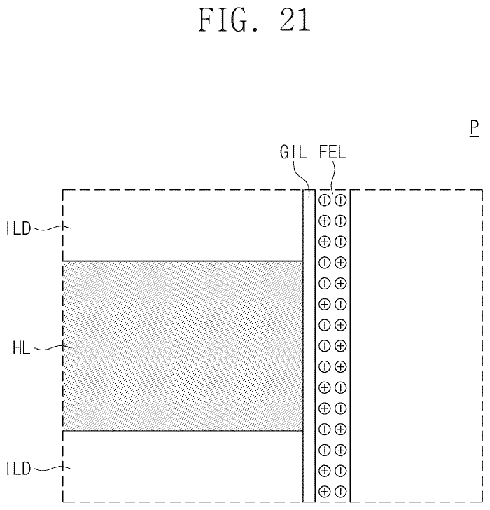

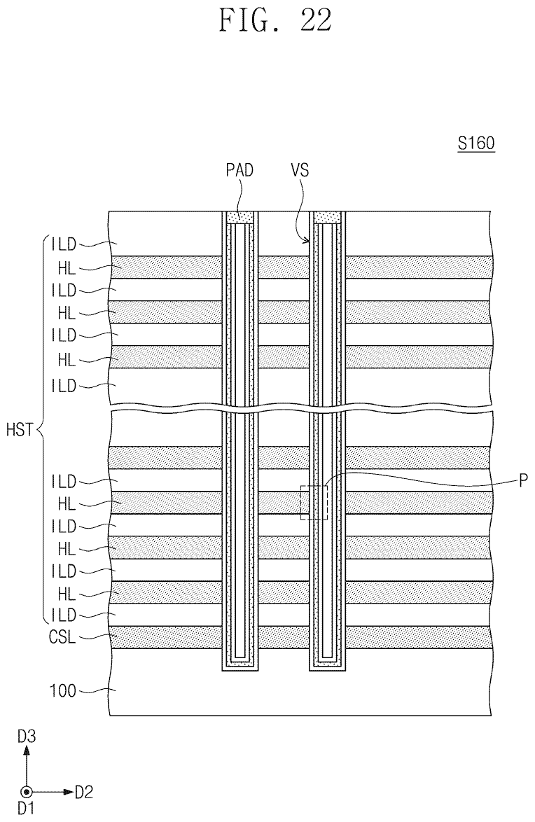

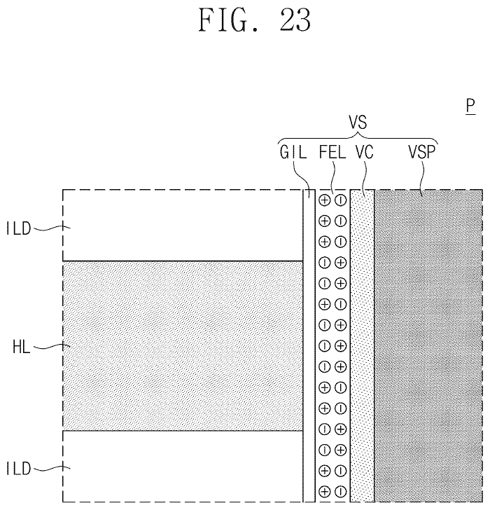

FIG. 11 is a flowchart illustrating a method for fabricating a semiconductor memory device according to the present disclosure. FIGS. 12 to 23 are views to describe the fabricating method of FIG. 11 step by step. FIGS. 12 to 14, FIG. 16, FIG. 18, FIG. 20, FIG. 22, and FIG. 24 correspond to cross-sectional views taken along line I-I′ of FIGS. 3 and 4 in the process of fabricating the semiconductor memory device. FIGS. 15, 17, 19, 21, and 23 are enlarged views of regions P of FIGS. 14, 16, 18, 20, and 22, respectively. Hereinafter, the method for fabricating the semiconductor memory device will be described in detail with reference to FIGS. 11 to 24.

Referring to FIG. 12, a temporary stack structure HST may be disposed on the substrate 100 and may extend in the first direction D1. The temporary stack structure HST may include sacrificial layers HL and insulating layers ILD alternately stacked in the third direction D3 (that is, the vertical direction) perpendicular to the first and second directions D1 and D2 crossing each other.

The common source line CSL may be interposed between the substrate 100 and the temporary stack structure HST. The common source line CSL may extend in the first direction D1 in parallel with the stack structure ST. The common source line may include a semiconductor material and a conductive material.

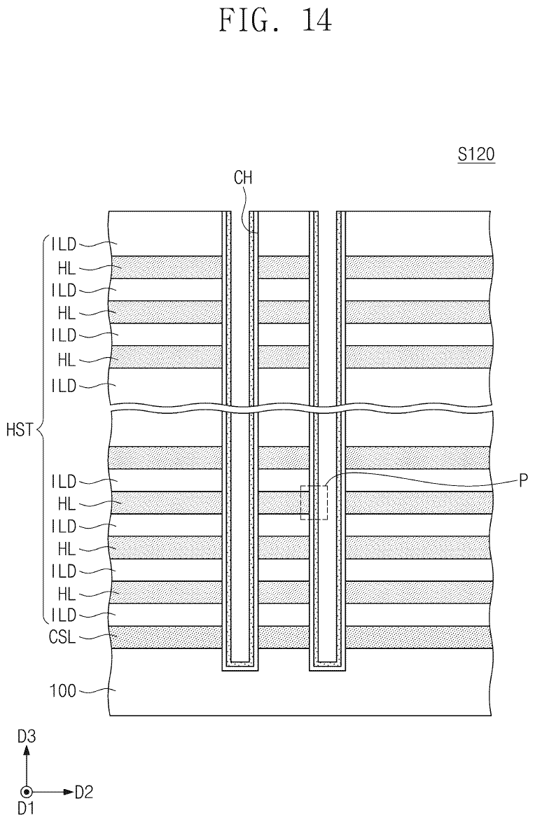

Referring to FIGS. 11 and 13, in step S110, channel holes CH may be formed in the temporary stack structure HST. Each channel hole CH may completely pass through the temporary stack structure HST and the common source line, and may pass through a portion of the top surface of the substrate 100.

Referring to FIGS. 11, 14, and 15, the gate insulating layer GIL and a ferroelectric layer FEL may be sequentially formed on the channel hole CH in step S120. The ferroelectric layer FEL may be formed on the inner sidewall of the channel hole CH.

The ferroelectric layer FEL may have the form of a pipe or a macaroni form having the closed lower end. The ferroelectric layer FEL may be formed to have a U-shape having an inner space. The gate insulating layer GIL may be provided between the ferroelectric layer FEL and the inner wall of the channel hole CH to surround the ferroelectric layer FEL.

Referring to FIGS. 11, 16, and 17, in step S130, a stress control layer SEL may be formed on an inner wall of the ferroelectric layer FEL. The stress control layer SEL may be directly formed on the inner wall of the ferroelectric layer FEL. The stress control layer SEL may be formed to cover the entire inner wall of the ferroelectric layer FEL. The stress control layer SEL may be conformally formed, and may be formed in a U-shape having an inner space.

As described later, since the stress control layer SEL is formed to make contact with the inner wall of the ferroelectric layer FEL, stress with the ferroelectric layer FEL is caused during a cooling process, thereby improving orthorhombic characteristics of the ferroelectric layer FEL.

Referring to FIGS. 11, 18, and 19, in step S140, the cooling process may be performed on the stress control layer SEL. The cooling process may include a process of rapidly cooling the stress control layer SEL and the ferroelectric layer FEL by injecting low-temperature coolant into a space on an inner wall of the stress control layer SEL.

In the process of performing the rapid cooling process, the ferroelectric characteristic of the ferroelectric layer may be improved in proportion to a contact area between the ferroelectric layer FEL and the stress control layer SEL and an area in which the cooling process is performed. According to the present disclosure, the stress control layer SEL is formed to cover the entire inner wall of the ferroelectric layer FEL, and cooling water is directly provided to the entire inner wall of the stress control layer SEL, thereby improving ferroelectric characteristics by the cooling process.

Referring to FIGS. 11, 20, and 21, in step S150, the stress control layer SEL may be removed.

According to an embodiment, the stress control layer SEL may be completely removed.

According to another embodiment, only a portion of the stress control layer SEL may be removed, which is different from the drawing. When a portion of the stress control layer SEL is removed, a portion of the stress control layer SEL remaining on the ferroelectric layer FEL may have the substantially uniform thickness. The thickness of the stress control layer SEL may be less than the thickness of the ferroelectric layer and may be less than the thickness of the vertical channel layer VC. For example, the thickness of the stress control layer SEL may be 5 to 50 nanometers.

Referring to FIGS. 11, 22, and 23, in step S160, a vertical channel layer VC, the conductive pad PAD, and the vertical semiconductor layer VS may be formed on an inner wall of the stress control layer SEL to form the vertical structure VS.

According to an embodiment, the stress control layer SEL may remain between the vertical channel layer VC and the ferroelectric layer FEL, which is not illustrated in the drawing.

According to an embodiment, the gate insulating layer may be additionally formed between the vertical channel layer VC and the vertical semiconductor layer VSP, which is not illustrated in the drawing.

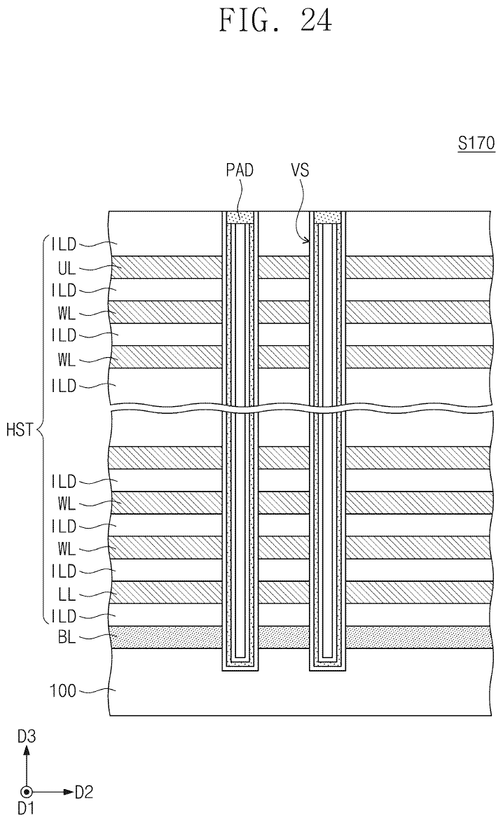

Referring to FIGS. 11 and 24, in step S170, a word line replay process may be performed.

The performing of the word line replace process is to form the gate electrodes LL, WL, and UL by removing the sacrificial layers HL from the temporary stack structure HTS and providing a conductive material. When the word line replace process is finished, the sacrificial layers of the temporary stack structure HST are replaced with the gate electrodes LL, WL, and UL to form the stack structure ST.

Referring back to FIG. 4, after step S170 is performed, the separation structure SS may be formed through the stack structure ST. The bit lines BL may be connected to the conductive pad PAD of each vertical structure VS through the bit line contact plugs BLPG to be connected to the vertical channel layer VC.

According to an embodiment, there may be provided a semiconductor memory device which consumes lower power and provides a higher data rate. According to an embodiment, there may be provided a method for fabricating a semiconductor memory device which consumes lower power and provides a higher data rate.

The above description refers to detailed embodiments for carrying out the invention. Embodiments in which a design is changed simply or which are easily changed may be included in the present disclosure as well as an embodiment described above. In addition, technologies that are easily changed and implemented by using the above embodiments may be included in the present disclosure. While the present disclosure has been described with reference to exemplary embodiments thereof, it will be apparent to those of ordinary skill in the art that various changes and modifications may be made thereto without departing from the spirit and scope of the present disclosure as set forth in the following claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method for fabricating a semiconductor memory device, the method comprising:
forming a channel hole inside a temporary stack structure including sacrificial layers and insulating layers alternately stacked on each other;
forming a ferroelectric layer inside the channel hole;
forming a stress control layer on an inner sidewall of the ferroelectric layer;
performing a cooling process on an inner sidewall of the stress control layer;
removing at least a portion of the stress control layer after the cooling process is performed;
forming a vertical structure by sequentially forming a vertical channel layer and a vertical semiconductor layer on the ferroelectric layer; and
removing the sacrificial layers from the temporary stack structure and forming gate electrodes.

2. The method of claim 1, wherein the ferroelectric layer is doped with at least one material of HfOx, Al, Zr, or Si to have an orthorhombic crystal structure.

3. The method of claim 2, wherein the stress control layer includes:
a material causing stress together with the ferroelectric layer during the cooling process.

4. The method of claim 1, wherein the performing of the cooling process includes:
rapidly cooling the stress control layer and the ferroelectric layer by injecting cooling water into the inner sidewall of the stress control layer.

5. The method of claim 4, wherein the performing of the cooling process includes:
performing the cooling process by directly providing the cooling water into an entire portion of the inner sidewall of the stress control layer.

6. The method of claim 1, wherein a thickness of the stress control layer, which remains between the ferroelectric layer and the vertical channel layer, is less than a thickness of the ferroelectric layer, when the at least a portion of the stress control layer is removed through the process of removing the at least a portion of the stress control layer.

7. The method of claim 6, wherein the thickness of the stress control layer, which remains between the ferroelectric layer and the vertical channel layer, is in a range of 5 nanometer to 50 nanometers.

8. The method of claim 1, wherein the vertical channel layer is directly provided on the ferroelectric layer, when the stress control layer is completely removed through the process of removing the at least a portion of the stress control layer.

9. The method of claim 1, wherein the forming of the vertical structure by sequentially forming the vertical channel layer and the vertical semiconductor layer on the ferroelectric layer includes:
sequentially forming a gate insulating layer, the vertical channel layer, and the vertical semiconductor layer on the ferroelectric layer.

10. The method of claim 1, wherein the performing of the gate electrodes is performed after forming the vertical structure.

11. A semiconductor memory device comprising:
a stack structure including gate electrodes and insulating layers alternately stacked on a substrate; and
a vertical structure provided inside the stack structure,
wherein the vertical structure includes:
a vertical semiconductor layer having a pillar shape;
a ferroelectric layer provided between the gate electrodes and the vertical semiconductor layer;
a vertical channel layer interposed between the ferroelectric layer and the vertical semiconductor layer; and
a stress control layer interposed between the ferroelectric layer and the vertical channel layer, and
wherein the stress control layer is directly connected to the ferroelectric layer.

12. The semiconductor memory device of claim 11, wherein the ferroelectric layer is doped with at least one material of HfOx, Al, Zr, or Si to have an orthorhombic crystal structure.

13. The semiconductor memory device of claim 12, wherein the stress control layer is a semiconductor memory device including a material to cause stress with the ferroelectric layer during a cooling process.

14. The semiconductor memory device of claim 11, wherein a thickness of the stress control layer is less than a thickness of the ferroelectric layer.

15. The semiconductor memory device of claim 14, wherein the thickness of the stress control layer is in a range of 5 nanometer to 50 nanometers.

16. The semiconductor memory device of claim 11, wherein the vertical structure further includes:
a gate insulating layer between the ferroelectric layer and the gate electrodes.

17. The semiconductor memory device of claim 11, wherein the vertical structure further includes:
a gate insulating layer between the ferroelectric layer and the vertical channel layer.
